(19) United States
(12) Patent Application Publication
(10) Pub. No.: US 2013/0010410 A1
(43) Pub. Date: Jan. 10, 2013

(54) Apparatus and Method for Portable Electronic Device

(75) Inventors: Mika Hautamäki, Vesilahti (FI); Timo Herranen, Viiala (FI)

(73) Assignee: NOKIA CORPORATION, Espoo (FI)

(21) Appl. No.: 13/509,787

(22) PCT Filed: Dec. 2, 2009
(86) PCT No.: PCT/FI09/50971

§ 371 Date: May 14, 2012

(51) Int. Cl. H05K 7/00; B23P 17/04

(52) U.S. Cl. 361/679.01; 29/428

(57) ABSTRACT

In accordance with an example embodiment of the present invention an apparatus (100) is provided, comprising: a first housing (101) comprising a first user interface (103), the first user interface extends along a first plane, and a second housing (102) comprising a second user interface (104), the second user interface extends along a second plane; the apparatus configured to provide a first position which is a compact position, and a second position in which the second user interface is exposed, and in which the second plane has been moved relatively toward the first plane; and a constraint member configured to constrain movement of the second user interface when the first user interface and second user interface are at least partly overlapping.

### TECHNICAL FIELD

The present application relates generally to portable electronic devices.

### BACKGROUND

Portable electronic devices may comprise two housings, which are movable in relation to each other. Housings may be configured to move in sliding, folding, swiveling, or other ways in relation to each other. The two housings comprise user interface elements such as displays and keypads. These form factors are popular because they allow the device to be adjusted to needs of the user according to the current use situation. Closed configuration of the form factor enables the device to be compact, and some user interface elements are protected. In open configuration, the user interface surface of the device is expanded for additional capabilities.

### SUMMARY

Various aspects of examples of the invention are set out in the claims. As in a first aspect of the present invention, an apparatus is provided, comprising a first housing comprising a first user interface, the first user interface extends along a first plane, and a second housing comprising a second user interface, the second user interface extends along a second plane; the apparatus configured to provide a first position which is a compact position, and a second position in which the second user interface is exposed, and in which the second plane has been moved relatively toward the first plane; and a constraint member configured to constrain movement of the second user interface when the first user interface and the second user interface are at least partly overlapping.

As in a second aspect of the present invention, a method is provided, the method comprising: providing a first housing comprising a first user interface, the second user interface extends along a second plane; providing a second housing comprising a second user interface, the second user interface extends along a second plane; configuring the apparatus to provide a first position which is a compact position, and a second position in which the second user interface is exposed, and in which the second plane has been moved relatively toward the first plane; and configuring a constraint member to constrain movement of the second user interface when the first user interface and the second user interface are at least partly overlapping.

### BRIEF DESCRIPTION OF THE DRAWINGS

For a more complete understanding of example embodiments of the present invention, reference is now made to the following descriptions taken in connection with the accompanying drawings in which:

FIG. 1a is an exterior view of a device in its first position in accordance with an example embodiment of the invention;

FIG. 1b is a cross-sectional view of the device in its first position in accordance with an example embodiment of the invention;

FIG. 2a is an exterior view of the device in a position between the first and second positions in accordance with an example embodiment of the invention;

FIG. 2b is a cross-sectional view of the device in another position between the first and second positions in accordance with an example embodiment of the invention;

FIG. 3a is an exterior view of the device in its second position in accordance with an example embodiment of the invention;

FIG. 3b is a cross-sectional view of the device in its second position in accordance with an example embodiment of the invention;

FIG. 4a is a cross-sectional view of the device in the first position in accordance with an example embodiment of the invention;

FIG. 4b is a cross-sectional view of the device when moved away from the first position in accordance with an example embodiment of the invention;

FIG. 4c is a cross-sectional view of the device when moved further away from the first position in accordance with an example embodiment of the invention;

FIG. 4d is a cross-sectional view of the device in the second position in accordance with an example embodiment of the invention;

FIG. 5 is a detail view of the device according to certain embodiments;

FIG. 6a is a detail view illustrating action of a constraint member in accordance with an example embodiment of the invention;

FIG. 6b is a detail view illustrating action of the constraint member in accordance with an example embodiment of the invention;

FIG. 6c is a detail view illustrating action of the constraint member in accordance with an example embodiment of the invention;

FIG. 7 illustrates internal details of the device according to certain example embodiments;

FIG. 8a is a cross-sectional view of the device in the first position in accordance with an example embodiment of the invention;

FIG. 8b is a cross-sectional view of the device when moved away from the first position in accordance with an example embodiment of the invention;

FIG. 8c is a cross-sectional view of the device when moved further away from the first position in accordance with an example embodiment of the invention;

FIG. 8d is a cross-sectional view of the device in the second position in accordance with an example embodiment of the invention;

FIG. 9 shows rails and a bistable member in accordance with an example embodiment of the invention;

FIG. 10 a perspective view of a device in accordance with an example embodiment of the invention; and

FIG. 11 is a flowchart illustrating a method according to certain example embodiments of the invention.

### DETAILED DESCRIPTION OF THE DRAWINGS

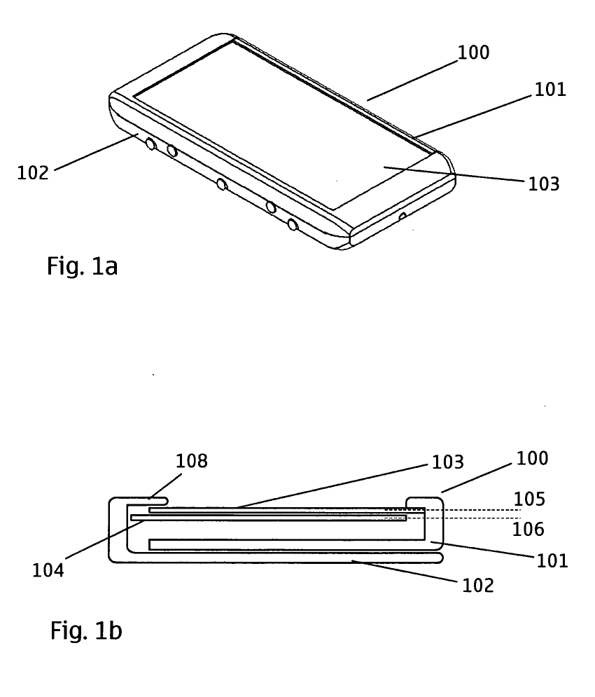

Example embodiments of the present invention and its potential advantages are understood by referring to FIGS. 1 through 11 of the drawings.

Referring to FIGS. 1, 2, and 3, there are shown perspective and cross-sectional views of a device 100 incorporating features of the invention. In certain embodiments of the invention the device 100 may be a portable communications device, such as a mobile phone. However, features of the invention could be used in any type of portable electronic device such as a portable computer, gaming device, multimedia device, navigation device, or Persona Digital Assistant (PDA) device. Although the invention will be described with reference to example embodiments shown in the drawings, it should be understood that many alternative embodiments are possible, and any suitable size, shape, materials, and elements may be used.

In FIG. 1a the device 100 is shown in its first, closed position. In some embodiments the first position may also be characterized as a compact position of the device 100. The device comprises a first housing 101 and a second housing 102 which are movable in relation to each other in a slidable manner. The first housing 101 comprises a first user interface 103, which is accessible when the device 100 is in the first position. In certain example embodiments the first user interface 103 may comprise a display. In certain further embodiments the display may be a touch display. However in some embodiments the user interface 103 may comprise other suitable user interface elements, such as an input device, which may be a keypad, touchpad, joystick, scroll wheel, button switch, or other type of device.

In FIG. 1b a cross-sectional view of the device 100 in the first position is shown. The second housing 102 comprises a second user interface 104. In certain example embodiments the second user interface 104 may comprise a display. In certain further embodiments the display may be a touch display. However in some embodiments the user interface 104 may comprise other suitable user interface elements, such as an input device, which may be a keypad, touchpad, joystick, scroll wheel, button switch, or other type of device. As seen in FIG. 1b, the first user interface 103 extends along a first plane 105, and the second user interface 104 extends along a second plane 106, substantially parallel with the first plane 105. In the first position the first plane 105 and the second plane 106 are different. As shown in FIG. 1b., the first user interface 103 and the second user interface 104 are substantially overlapping in the first position, and the second user interface 104 may not be accessible from the exterior of the device. The second housing 102 may comprise a protrusion 108, configured to cover a possible gap between the first user interface 103 and the second housing 102.

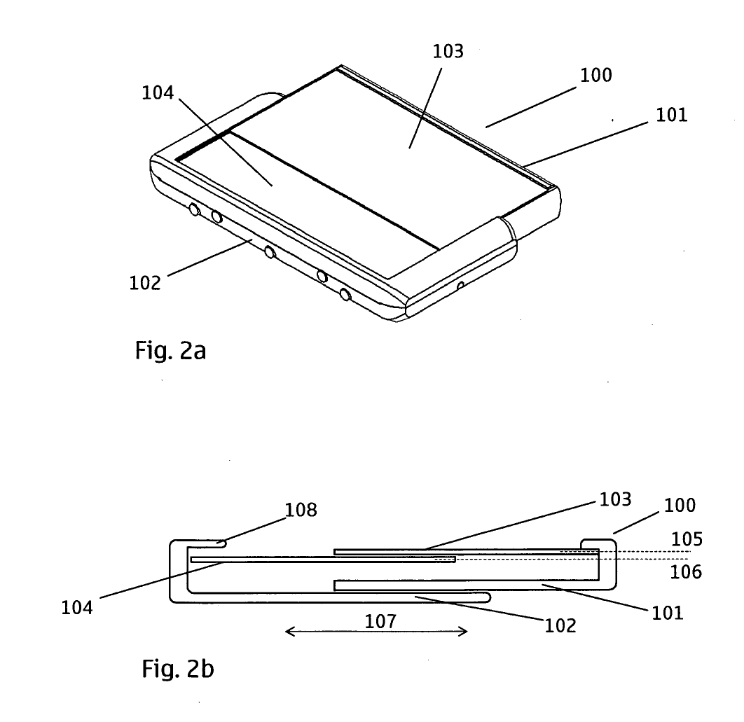

In FIG. 2a the device 100 is shown in a transitional position, in which the first housing 101 has been moved in relation to the second housing 102 away from the first position. The second user interface 104 is partially exposed. FIG. 2b shows a cross-sectional view of the device 100 in the transitional position. As shown in the figure, the first housing 101 and the second housing 102 are configured to be movable along an axis 107. The first user interface plane 105 and the second user interface plane 106 remain parallel in relation to each other, and substantially separated from each other. In other words, the first user interface 103 and the second user interface 104 are not significantly contacting each other.

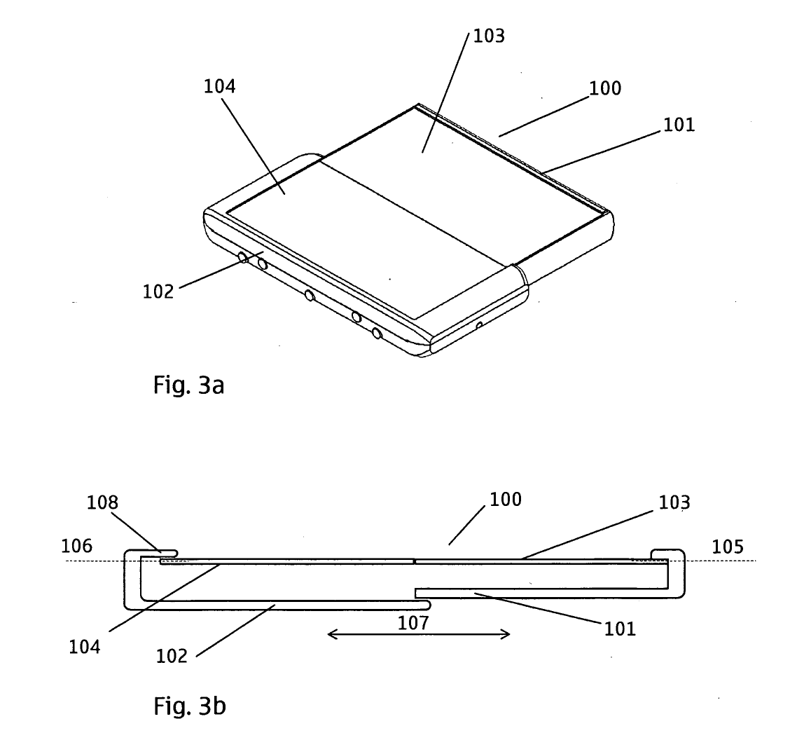

In FIG. 3a the device 100 is shown in its second, open position, in which both the first user interface 103 and the second user interface 104 are exposed and accessible. In some embodiments, the second position may also be characterized as an extended position of the device 100. A cross-sectional view of the second position in FIG. 3b shows that the second user interface 104 is now positioned in such a way that the second user interface plane 106 remains parallel with the first plane 105, but it has been moved relatively toward the first user interface plane 105. In some embodiments the first user interface 103 and the second user interface 104 may be substantially level with each other in the second position of the device 100. As an example, the first user interface plane 105 and the second user interface plane 106 become the same. In certain embodiments the first user interface 103 and the second user interface 104 may form a substantially contiguous user interface when the device 100 is in the second position. In some embodiments the first user interface 103 and the second user interface 104 may be touching each other, or almost touching, for example any separation between the first user interface 103 and the second user interface 104 is small relative to the dimensions of the device 100. In certain embodiments the first housing 101 and the second housing 102 may be configured for maximum extension in relation to each other when the device 100 is in the second position. In other words, the first housing 101 and the second housing 102 are at an end of their movement range in relation to each other. The protrusion 108 is configured to cover a possible gap between the second user interface 104 and the second housing 102.

In certain embodiments, capability of the device 100 to provide two user interfaces may be used to create various user interface capabilities of software applications. In an embodiment a first operational mode may provide an application to an end user; when the device is in a second operational mode the second user interface may provide content dependent upon the application in the first operational mode. By way of example, the first user interface 103 and the second user interface 104 may comprise displays which are used to display different parts of a document, image, or web page, or other screen object. It may also be possible to display different screen objects on different displays. A still further example is to use a first display to provide a soft keypad on a touch display for writing on a second display. A still further example is to enlarge a screen object, such as an image, video, or web page to extend over both displays when the device is moved from the first operational mode to the second operational mode. A still further example is an application configured to deploy an additional user interface element when a transition from the first operational mode to the second operational mode occurs, or to expand an already deployed user interface element. For example, a messaging application open on the first user interface in the first operational mode may be configured to deploy a soft keypad on the second user interface when transition from the first operational mode to the second operational mode occurs. A still further example is to provide a text processing application that takes advantage of both user interfaces. A still further example is that one a screen object uses the complete user interface surface of one user interface, but occupies only a part of the other. Many other features and combinations of features are also possible. A user interface may be switched to an unpowered or power-conserving state in certain positions of the device in order to conserve power. A processor may be configured to detect position of the device 100, and switch the operating state of the user interfaces accordingly. For example, the second user interface 104 may be switched to a power-conserving state when the device 100 is in the first position.

It should be noted that in different embodiments the device 100 may comprise various structural elements which for the sake of clarity are not shown in the figures. These may comprise: electronic circuitry, speaker, microphone, power source, connection ports, transceiver, antenna, and other type of elements.

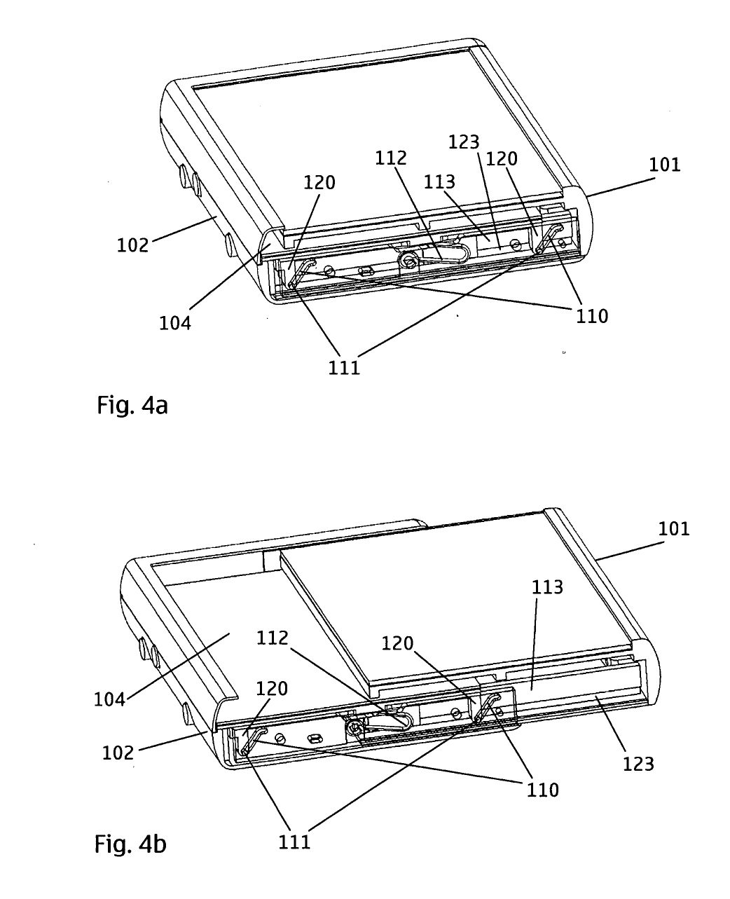

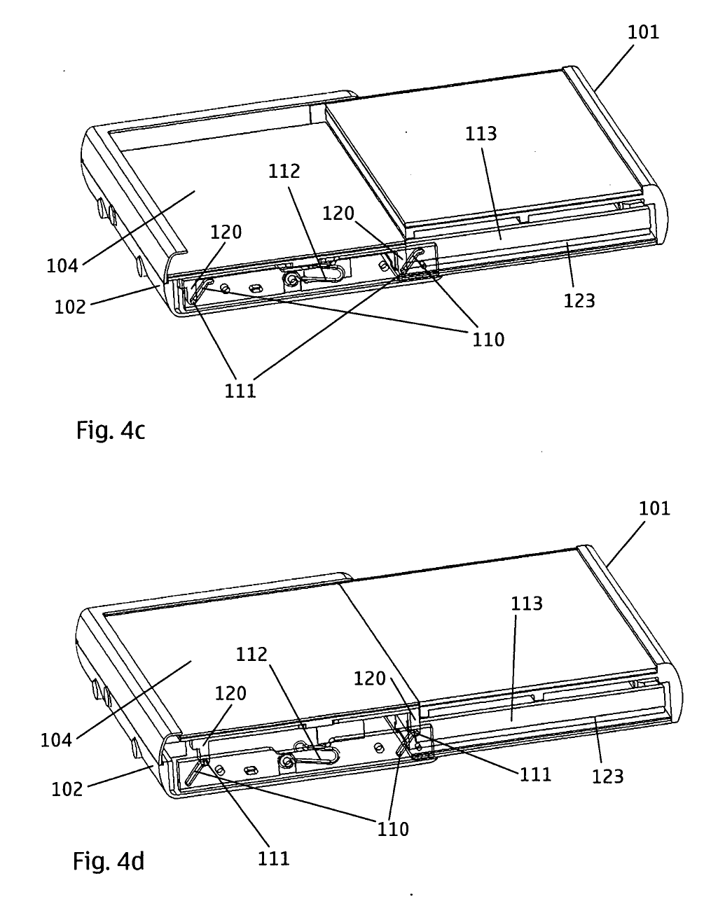

Reference is now made to FIGS. 4a, 4b, 4c, and 4d, which are cross-sectional views of the device 100 in various positions. As illustrated in the drawings, the second housing 102 comprises one or more grooves 110. The second user interface 104 comprises a second projecting member 111, which is configured to couple slidably with the groove 110. In certain embodiments there may be a plurality of second projecting members 111, configured to couple with a plurality of grooves 110. In certain embodiments, the sliding movement of the one or more second projecting members 111 along the one or more grooves 110 guides movement of the second user interface 104 in relation to the second housing 102. In certain example embodiments there may be provided a spring member 112, which is coupled to the second housing 102 and the second user interface 104, configured to drive movement of the second user interface 104. In some embodiments there may be a plurality of the spring members 112. The drawings also show a constraint member 113, which is housed in the first housing 101, and moves slidably in relation to the second housing 102. In the first position the constraint member 113 projects at least partly to the inside of the second housing 102, and in the second position the constraint member 113 may be located substantially outside the second housing 102. The views of the device 100 in its different positions illustrate how the said parts cooperate with each other. Also shown in the figures are arm members 120, and guide structures 123, which will be described in detail later.

In FIG. 4a, the device 100 is shown in the first position, in which the second user interface 104 is held by the constraint member 113 in its stowed position. In FIG. 4b, the device 100 is shown in a position in which the first housing 101 and the second housing 102 have been moved away from the first position. Also in this position, the second user interface 104 is held by the constraint member 113 in its stowed position. In FIG. 4c, the device 100 is shown in a position in which the first housing 101 and the second housing 102 have been moved still further away from the first position to a point where movement of the second user interface 104 is no longer constrained by the constraint member 113. Finally, FIG. 4d shows the device 100 in the second position. In some example embodiments of the invention, the position shown in FIG. 4d may the position in which the first housing 101 and the second housing 102 are at an end of their movement range in relation to each other. As shown in the drawing, the second user interface 104 is now substantially level with the first user interface 103. The first user interface 103 and the second user interface may thus form a substantially contiguous user interface surface.

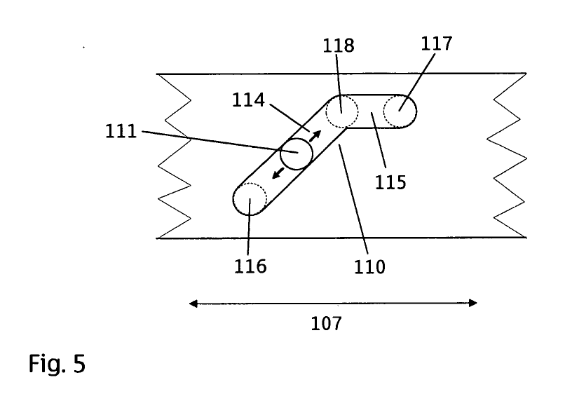

FIG. 5 shows a detail view of the coupling between a groove 110 and a second projecting member 111. The groove 110 may be shaped for receiving the projecting members 111. The groove 110 and the second projecting member 111 may be of corresponding dimensions. They may be suitably dimensioned in such a way that the second projecting member 111 is substantially of an equal width with the groove 110. It should be understood that a necessary amount of clearance may be provided to allow movement of the second projecting member 111 in the groove 110 with sufficiently low friction. In certain embodiments, the groove 110 comprises a section 114 which is inclined with respect to the axis 107, and a section 115 which is substantially parallel to the axis 107. The groove 110 may further comprise a first endpoint 116, a second endpoint 117, and a transition point 118. The first endpoint 116 and the transition point 118 are connected by the inclined section 114 of the groove 110. The second endpoint 117 and the transition point 118 are connected by the parallel section 115 of the groove 110. The transition point 118 is the point where the inclined section 114 and the parallel section 115 are configured to connect with each other. The first endpoint 116 may correspond to the first position of the device 100 and the second endpoint 117 may correspond to the second position of the device 100. In certain example embodiments the spring member 112 (see FIGS. 4a, b, c, and d) may be configured to bias the second user interface surface 104 toward the second endpoint 117.

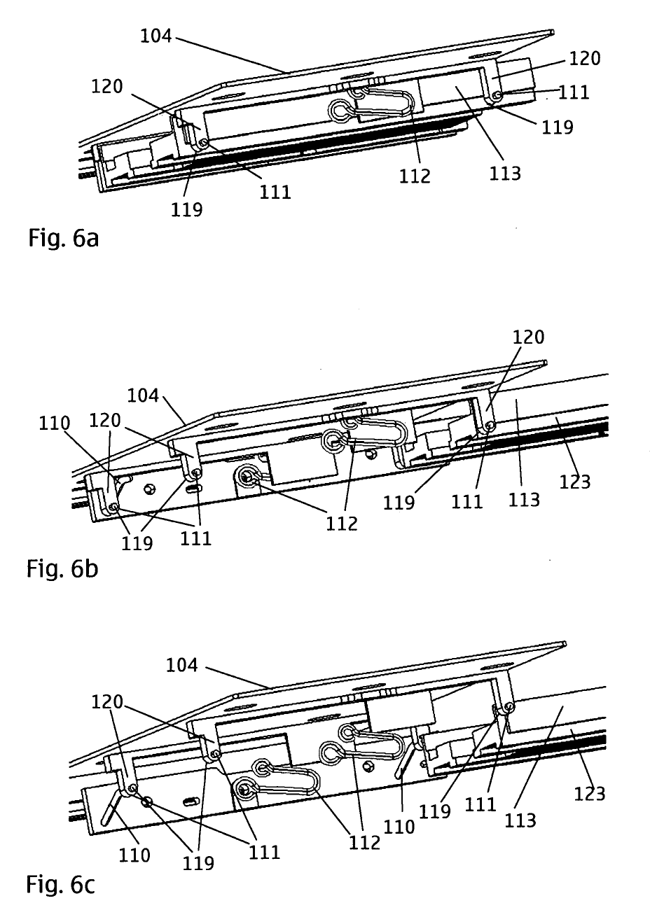

Reference is now made to FIGS. 6a, 6b, and 6c. When the device 100 is in the first position as shown in FIG. 6a, the constraint member 113 projects to the space inside the second housing 102. The constraint member 113 may be configured to couple slidably with one or more first projecting members 119 coupled with the second user interface 104. The constraint member 113 may be provided with one or more guide structures 123 which are configured to cooperate with the one or more first projecting members 119. In the first position the constraint member 113 constrains movement of the second user interface 104 in such a way that it remains substantially in the position where the one or more second projecting members 111 are at the first endpoints 116 illustrated in FIG. 5. It may thus prevent the one or more spring member 112 from moving the second user interface plane 106 toward the first user interface plane 105 (see FIG. 1b).

FIG. 6b shows the position of the constraint member 113 when the device 100 is in an intermediate position where it has been moved away from the first position, but the first user interface 103 and the second user interface 104 are still overlapping at least partly. The constraint member 113 continues to constrain the second user interface surface 104 in the position where the one or more second projecting members 111 are at the first endpoints 116 of the grooves 110. The constraint member 113 may be dimensioned in such a way that the second user interface 104 in constrained in the said position until movement of the first housing 101 and second housing 102 toward the second position has proceeded to a point where the first user interface 103 and the second user interface 104 are no longer overlapping. When movement of the first housing 101 and the second housing 102 toward the second position continues past the said point, the second user interface surface 104 is no longer constrained by the constraint member 113. Biasing action of the one or more spring members 112 may then be allowed to move the second user interface plane 105 in such a way that the one or more second projecting members 111 move along the grooves 110 toward the transition points 118 (see FIG. 5). When the second projecting members 111 have reached the transition points 118, the second user interface plane 105 may be substantially at the same level with first user interface plane 106. When the first housing 101 and second housing 102 are moved still further toward the second position, the one or more second projecting members 111 move along the parallel sections 115 of the grooves toward the second endpoints 117, which correspond to the second position. FIG. 6c shows details of the device 100 in the second position.

When the device is moved from the second position toward the first position, the movements described in FIGS. 6a, 6b, and 6c take place in the reverse order.

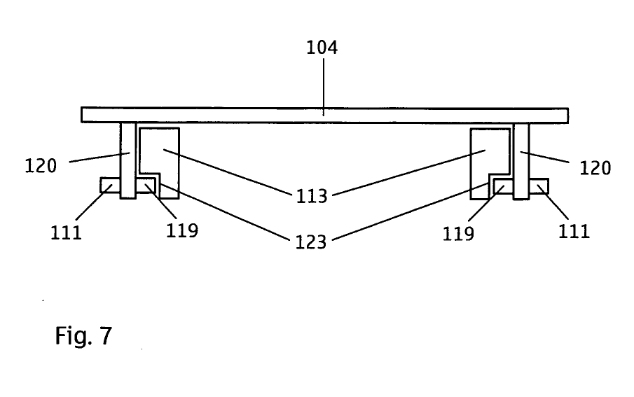

In FIG. 7, a cross-sectional view is shown of some details according to certain embodiments of the invention. As illustrated in the drawing, the second used interface 104 is provided with one or more arm members 120 which protrude from the second user interface 104 from the surface opposite to the surface of the second user interface 104 which is and exterior surface in the second position of the device 100. A second projecting member 111 and a first projecting member 119 may be integrated in an arm member 120. In certain example embodiments they may be on opposite sides of the arm member 120. The device 100 may include a plurality of said arm members 120. Also shown in the drawing is the constraint member 113, which is an element housed in the first housing 101, configured to constrain movement of the second user interface 104 in certain relative positions of the first housing 101 and the second housing 102. The constraint member 113 may comprise one or more distinct parts. In the position shown in the drawing, the constraint member 113 is holding the second user interface 104 in the stowed position. As further shown in the drawing, the constraint member 113 may be provided with one or more guide structures 123, which are configured to cooperate with the first projecting members 119. The one or more guide structures 123 are suitably shaped and dimensioned to allow sliding movement of the first projecting member 119 in relation to the constraint member 113. The guide structure 123 can be a recess, rail, indentation, or other suitable shape provided in the constraint member 113. The guide structure may also be separate part.

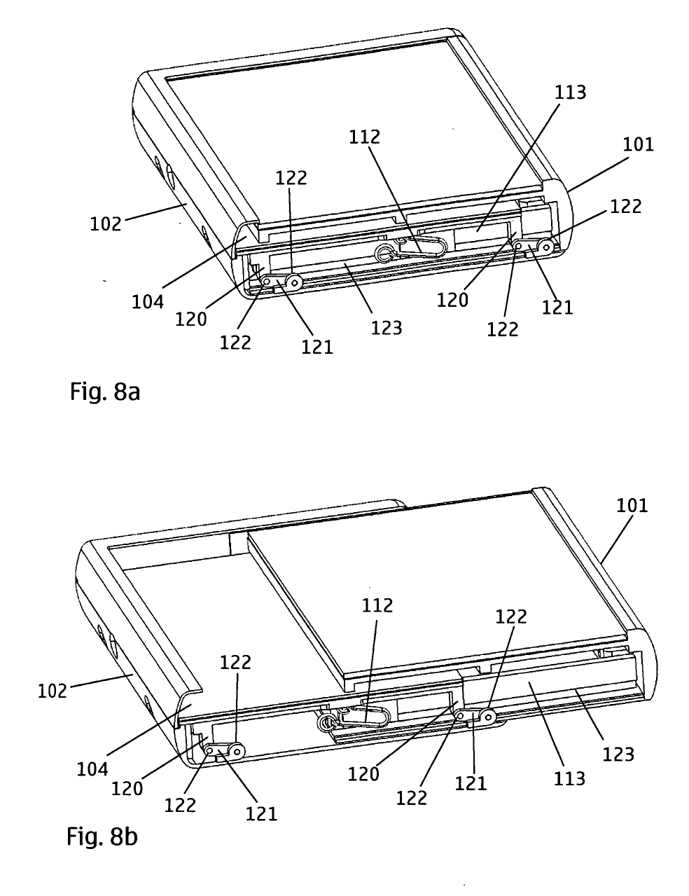

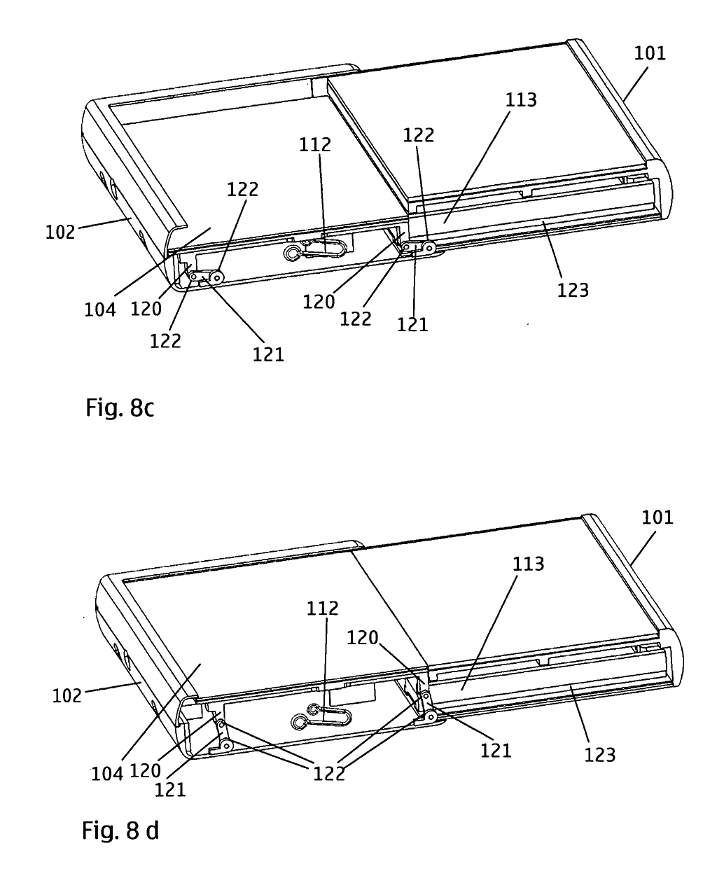

It should be understood that many variations are possible without departing from the scope of the invention. In some embodiments described above, movement of the second user interface 104 is guided by one or more second projecting members 111 and grooves 110, the second projecting 111 members being configured to couple slidably with the grooves 110. However, other types of guiding mechanisms are possible within scope of the invention. FIGS. 8a, 8b, 8c, and 8d illustrate an example embodiment in which movement of the second user interface 104 may be guided with a mechanism comprising a connecting member 121, which comprises two end portions 122, wherein one end portion is hinged to the second housing 102, and other end portion is hinged to the second user interface 104. In some embodiments the end portion 122 which is hinged to the second user interface 104 may be coupled to an arm member 120. A plurality of connecting members 121 may be provided in the device 100. It is also possible to combine features of different guiding mechanisms. As an example, one side of the second user interface 104 may be guided with a mechanism comprising one or more second projecting members 111 and grooves 110, while another side is guided with a mechanism comprising one or more connecting members 121 hinged from one end to the second housing 102 and from one end to the second user interface 104.

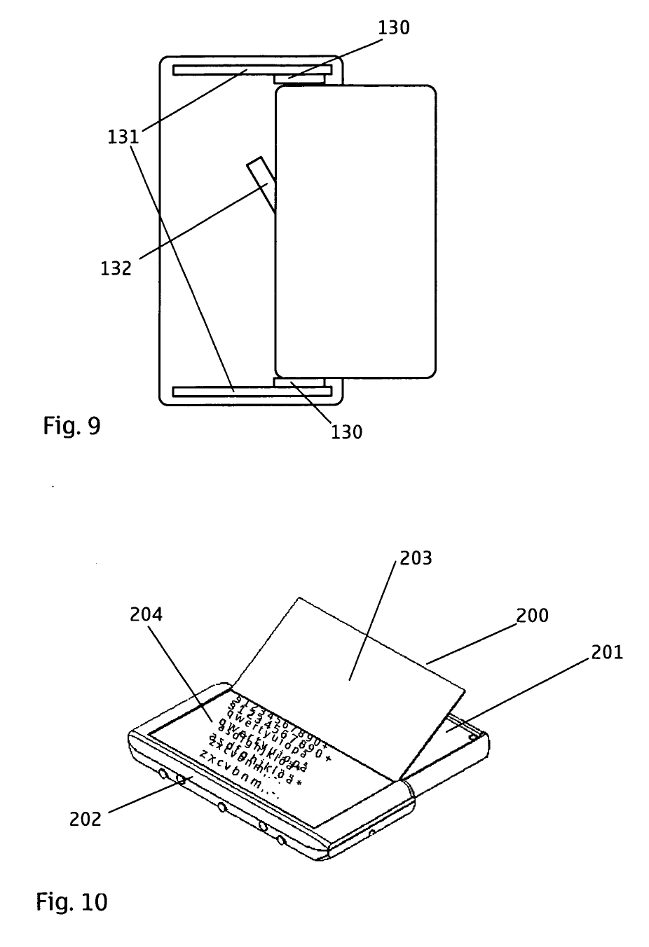

FIG. 9 shows how the first housing 101 and the second housing 102 are coupled to each other in certain embodiments of the invention. The first housing may 101 be provided with a first set of rails 130, which are configured to receive a second set of rails 131 provided in the second housing 102. In FIG. 9, two rails are provided in each housing, and the rails are located proximate to edges of the device. However, the number of rails may be different from two, and they can be provided in any suitable location without departing from the scope of the invention.

In certain embodiments of the invention, the device may be provided with a bistable member 132 coupled to the first housing 101 and the second housing 102, and configured to at least partly drive movement of the first housing 101 and the second housings 102. The bistable member 132 may be configured to bias the first housing 101 and the second housing 102 toward the first position when the first housing 101 and the second housing 102 are at or proximate to the first position. When the first housing 101 and the second housing 102 are moved for example manually toward the second position against biasing force of the bistable member 132, the bistable member 132 begins to bias the first housing 101 and the second housing 102 toward the second position when movement has proceeded past a suitably selected point between the first and second positions. Likewise, when the first housing 101 and the second housing 102 are moved from the second position toward the first position against biasing force of the bistable member 132, the bistable member begins 132 to bias the first housing 101 and the second housing 102 toward the first position when movement has proceeded past a suitably selected point between the first and second positions. However, certain other embodiments of the invention may not include the bistable member 132, but instead the first housing 101 and the second housing 102 may be configured to be movable manually without the effect of a bistable member.

FIG. 10 shows a device 200 according to a further example embodiment, comprising a first housing 201 and a second housing 202 which are movable in relation to each other. The first housing 201 comprises a first user interface 203, which may be accessible when the device is in the first position. The second housing 202 comprises a second user interface 204, which may be stowed in a first position of the device 200 and in use in a second position of the device 200. According to an example embodiment the first user interface 203 is hinged to the first housing 201, which allows rotable movement of the first user interface 203 in relation to the first housing 201. Depending on the position of the first user interface 203 along its range of rotable movement, the first user interface 203 and second user interface 204 may be either parallel with each other, or angled in relation to each other as shown in FIG. 10, when the device 200 is in the second position.

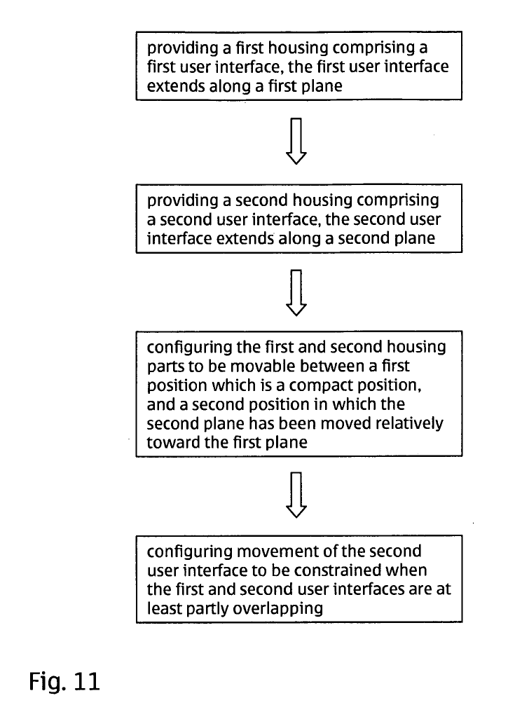

FIG. 11 shows a flowchart illustrating a method according to certain example embodiments of the invention. The method of assembling a device 100 comprises steps of providing a first housing 101 comprising a first user interface 103, the first user interface 103 extends along a first plane 105, and a second housing 102 comprising a second user interface 104, the second user interface 104 extends along a second plane 106. The method further comprises a step of configuring the first housing 101 and second housing 102 to be movable between a first position which is a compact position, and a second position in which the second plane 106 has been moved relatively toward the first plane 105. The method further comprises a step of configuring constraint member 113 to constrain movement of the second user interface 104 when the first user interface 103 and the second user interface 104 are at least partly overlapping.

In some embodiments described above the device is provided with first and second user interfaces which are substantially of the same size and shape. However, in certain other embodiments, the user interfaces may be of different size and shape. As an example, the second user interface 104 may be dimensioned to be shorter than the first user interface 103 along the direction of the axis 107. In certain example embodiments, length of the second user interface 104 in the direction of the axis 107 may be approximately half of the length of the first user interface 103 along the respective dimension.

Some embodiments described above relate to devices in wich housing sections are slidably coupled with each other. However it should be understood that in some other embodiments, the invention may be applied to form factors in which housing sections are coupled in other ways. For example, the device may comprise a first housing with a first user interface, and a second housing with a second user interface, the housing sections being foldably coupled with each other, wherein a second user interface is configured to move in relation to the second housing in order to minimize a gap between the first and second user interfaces in open position of the device.

Certain embodiments of the invention may relate to an apparatus comprising a first housing comprising a first user interface, the first user interface extends along a first plane, and a second housing comprising a second user interface, the second user interface extends along a second plane; the apparatus configured to provide a first position which is a compact position, and a second position in which the second user interface is exposed, and a constraint member configured to constrain movement of the second user interface when the first and second user interfaces are at least partly overlapping.

Without in any way limiting the scope, interpretation, or application of the claims appearing below, a technical effect of one or more of the example embodiments disclosed herein is to provide a device with two user interfaces, and to provide the device with an open and a closed position. Another technical effect of one or more of the example embodiments disclosed herein is that in closed position, a first user interface is accessible and a second user interface is stowed away, whereas in open position both user interfaces are accessible. Another technical effect of one or more of the example embodiments disclosed herein is that gap between the first user interface and the second user interface is diminished when the device is in the open position. The gap is thus made less disturbing to the user, and it may approach or become non-visible to the user. Another technical effect of one or more of the example embodiments disclosed herein is that the first and second user interfaces are substantially in the same plane when the device is in open position. Another technical effect of one or more of the example embodiments disclosed herein is that the first and second user interfaces for a substantially contiguous user interface when the device is in open position. Another technical effect of one or more of the example embodiments disclosed herein is that when the first and second user interfaces are overlapping, their movement is constrained in such a way that the first and second user interfaces are not significantly contacting each other, thus preventing friction between the user interfaces. Another technical effect of one or more of the example embodiments disclosed herein is that in the second position of the device, movement of the second user interface to a direction perpendicular to the second user interface plane is prevented. Another technical effect of some embodiments of the invention may be that viewing angle of the first user interface is adjustable.

Embodiments of the present invention may be implemented in software, hardware, application logic or a combination of software, hardware and application logic. The software, application logic and/or hardware may reside on a processor, memory or a readable medium. In an example embodiment, the application logic, software or an instruction set is maintained on any one of various conventional computer-readable media. In the context of this document, a “computer-readable medium” may be any media or means that can contain, store, communicate, propagate or transport the instructions for use by or in connection with an instruction execution system, apparatus, or device, such as a computer. A computer-readable medium may comprise a computer-readable storage medium that may be any media or means that can contain or store the instructions for use by or in connection with an instruction execution system, apparatus, or device, such as a computer.

If desired, the different functions discussed herein may be performed in a different order and/or concurrently with each other. Furthermore, if desired, one or more of the above-described functions may be optional or may be combined.

Although various aspects of the invention are set out in the independent claims, other aspects of the invention comprise other combinations of features from the described embodiments and/or the dependent claims with the features of the independent claims, and not solely the combinations explicitly set out in the claims.

It is also noted herein that while the above describes example embodiments of the invention, these descriptions should not be viewed in a limiting sense. Rather, there are several variations and modifications which may be made without departing from the scope of the present invention as defined in the appended claims.

1-31. (canceled)

32. An apparatus, comprising:
a first housing comprising a first user interface, the first user interface extends along a first plane, and
a second housing comprising a second user interface, the second user interface extends along a second plane;
the apparatus configured to provide a first position which is a compact position, and a second position in which the second user interface is exposed, and in which the second plane has been moved relatively toward the first plane;
and a constraint member configured to constrain movement of the second user interface when the first user interface and the second user interface are at least partly overlapping.

33. An apparatus as in claim 32,
wherein the first housing comprises the constraint member.

34. An apparatus as in claim 32, comprising a first projecting member coupled to the second user interface, the first projecting member being configured to couple slidably with the constraint member.

35. An apparatus as in claim 32, wherein movement of the second user interface is guided by a second projecting member and a groove, the second projecting member being configured to couple slidably with the groove.

36. An apparatus as in claim 35,
wherein the first housing and the second housing are configured to be movable along an axis with respect to each other, and the groove comprises a section which is inclined with respect to the axis.

37. An apparatus as in claim 35,
wherein the groove comprises a section which is parallel to the axis.

38. An apparatus as in claim 35,
wherein the groove is shaped for receiving the second projecting member.

39. An apparatus as in claim 35,
wherein the first projecting member and second projecting member are integrated in an arm member coupled to the second user interface.

40. An apparatus as in claim 32,
wherein movement of the second user interface is guided by a connecting member comprising a first end portion and a second end portion, wherein the first end portion is hinged to the second housing, and the second end portion is hinged to the second user interface.

41. An apparatus as in claim 32,
wherein the first and second user interfaces are substantially overlapping in the first position.

42. An apparatus as in claim 32,
wherein the first and second user interfaces are substantially in the same plane in the second position.

43. An apparatus as in claim 32,
wherein the first and second user interfaces form a substantially contiguous user interface surface in the second position.

44. An apparatus as in claim 32,
wherein the apparatus is a portable device.

45. An apparatus as in claim 32,
wherein the apparatus is configured to provide a first operational mode in the first position and a second operational mode in the second position, and an application is configured to deploy a user interface element when the device is moved from the first operational mode to the second operational mode.

46. A method comprising:
providing a first housing comprising a first user interface, the second user interface extends along a second plane;
providing a second housing comprising a second user interface, the second user interface extends along a second plane;
configuring the apparatus to provide a first position which is a compact position, and a second position in which the second user interface is exposed, and in which the second plane has been moved relatively toward the first plane; and
configuring a constraint member to constrain movement of the second user interface when the first user interface and the second user interface are at least partly overlapping.

47. A method as in claim 46,
wherein the first housing is configured to comprise the constraint member.

48. A method as in claim 46,
wherein a first projecting member, coupled to the second user interface, is configured to couple slidably with the constraint member.

49. A method as in claim 46,
wherein movement of the second user interface is configured to be guided by a second projecting member and a groove, the second projecting member being configured to couple slidably with the groove.

50. A method as in claim 46,
wherein movement of the second user interface is configured to be guided by a connecting member comprising a first end portion and a second end portion, wherein the first end portion is hinged to the second housing, and the second end portion is hinged to the second user interface.

51. An apparatus as in claim 46,
wherein the apparatus is configured to provide a first operational mode in the first position and a second operational mode in the second position, and an application is configured to deploy a user interface element when the device is moved from the first operational mode to the second operational mode.
